(19) United States
(12) Patent Application Publication
(10) Pub. No.: US 2020/0246924 A1
(43) Pub. Date: Aug. 6, 2020

(54) FLEXURE STAGE

(71) Applicant: Hiwin Mikrosystem Corp., Taichung City (TW)

(72) Inventors: Chun-Hsiang LI, Taichung City (TW); Chih-Kai FAN, Taichung City (TW); Yu-Jung CHANG, Taichung City (TW)

(21) Appl. No.: 16/267,975

(22) Filed: Feb. 5, 2019

(51) Int. Cl. B23Q 1/26

(52) U.S. Cl. CPC B23Q 1/262; H01L 21/68785

(57) ABSTRACT

A flexure stage with modularized flexure units for convenient manufacturing, assembly and repair is provided. The flexure stage comprises a base, a first carrier, a plurality of first flexure units, a gantry unit, a second carrier, and a plurality of second flexure units. The first carrier is separated from the base and reciprocated along a first axis. The first flexure units are disposed between the base and the first carrier wherein each of the first flexure units comprises flexibility in the first axis. The gantry unit is located on the base and separated from the first carrier. The second carrier is set on the gantry unit and reciprocated along a second axis. The second flexure units are disposed between the first carrier and the second carrier wherein each of the second flexure units comprises flexibility in the second axis.

### BACKGROUND OF THE INVENTION

### Field of the Invention

The invention relates to a stage, and more particularly to a flexure stage with higher precision and response.

### Description of the Related Art

As the development of the nanoscale science for the semiconductor, the stage with high precision and response is provided to meet the requirement. Due to the high speed movement, the carrier vibrates severely before stop state such that the setting time is lengthened to position the carrier precisely.

The conventional technology disclosed a stage system comprising a flexure frame to produce a compensating displacement to offset error and shorten the setting time. The conventional flexure frame is integrated as a whole to raise the strength thereof. However, the integrated flexure frame is not only hard manufacturing but repaired difficultly after assembling with the stage.

Furthermore, the conventional stage is driven by the stacked motors wherein the carrier is reciprocated along the linear guide rail in X-axis and Y-axis. However, the bottom motor bears the weight of the top motor thereby damaging the motor and shortening the life thereof.

Moreover, the driving motors are positioned within the stage and adjacent to the carrier such that the heat generated from the motors are barely dissipated to decrease the efficiency of the motor.

### SUMMARY OF THE INVENTION

In view of the disadvantages of prior art, the object of the present invention is to provide a flexure stage with modularized flexure units for convenient manufacturing, assembly and repair. Besides, the flexure stage comprises a gantry unit to support the driving unit and prevent from being damaged because of the weight of another driving unit.

To achieve the above object, the flexure stage comprises a base, a first carrier, a plurality of first flexure units, a gantry unit, a second carrier, and a plurality of second flexure units. The first carrier is separated from the base and reciprocated along a first axis. The first flexure units are disposed between the base and the first carrier wherein each of the first flexure units comprises flexibility in the first axis. The gantry unit is located on the base and separated from the first carrier. The second carrier is set on the gantry unit and reciprocated along a second axis. The second flexure units are disposed between the first carrier and the second carrier wherein each of the second flexure units comprises flexibility in the second axis.

The first flexure units and the second flexure units comprise multiple bending parts to provide flexibility in the first axis and the second axis.

In one embodiment of the present invention, each of the first flexure units comprises a first section located on the base, a second section connected with the first carrier and separated from the first section, and a first bending part coupled with the first section and the second section. The first section comprises an opening holding the first bending part and the second section; the first bending part comprises a first connection element, a first elastic element and a second elastic element wherein the first elastic element is bridged between the first connection element and the edge of the second section, and the second elastic element is bridged between the first connection element and the wall of the opening of the first section.

In one embodiment of the present invention, each of the second flexure units comprises a third section located on the first carrier, a fourth section connected with the second carrier and separated from the third section, and a second bending part coupled with the third section and the fourth section. The third section comprises an opening holding the second bending part and the fourth section; the second bending part comprises a third connection element, a third elastic element and a fourth elastic element wherein the third elastic element is bridged between the third connection element and the edge of the fourth section, and the fourth elastic element is bridged between the third connection element and the wall of the opening of the third section.

In one embodiment of the present invention, the flexure stage further comprises a first driving unit and a second driving unit to shorten the setting time and position the carrier precisely after high speed movement. The first driving unit is disposed between the base and the first carrier to activate the first carrier. The second driving unit is disposed between the gantry unit and the second carrier to activate the second carrier. Therefore, the flexure stage with the first flexure units and the second flexure units is provided to produce a compensating displacement to offset error and shorten the setting time.

In one embodiment of the present invention, the gantry unit supports the second stator of the second driving unit to prevent the first driving unit from being damaged because of the weight of the second mover. The gantry unit comprises a bridge above the base and two connections fastened at two ends of the base to hold the first carrier between the bridge and the base. Therefore, the second stator is not disposed in an enclosed configuration such that the heat generated from the second stator can be dissipated rapidly.

In one embodiment of the present invention, the second carrier comprises a plurality of fixtures associated with the fourth sections of the second flexure unit respectively to form a space where the second driving unit is disposed. Each fixture is separated from the second driving unit with a width W to prevent from the interference during the first carrier is activated by the first driving unit.

### BRIEF DESCRIPTION OF THE DRAWINGS

FIG. 1 is a schematic view of the flexure stage of the first embodiment of the present invention;

FIG. 2 is a schematic view of the flexure stage without the second carrier shown in FIG. 1;

FIG. 3 is a schematic view of the flexure stage without the gantry unit and the second flexure units shown in FIG. 2;

FIG. 4 is an exploded view of the flexure stage of the first embodiment of the present invention;

FIG. 5 is a top view of the first flexure unit of the first embodiment of the present invention;

FIG. 6 is a top view of the first flexure unit of the second embodiment of the present invention;

FIG. 7 is sectional view of the flexure stage of the first embodiment of the present invention; and

FIG. 8 is another sectional view of the flexure stage of the first embodiment of the present invention.

### DETAILED DESCRIPTION OF THE PREFERRED EMBODIMENTS

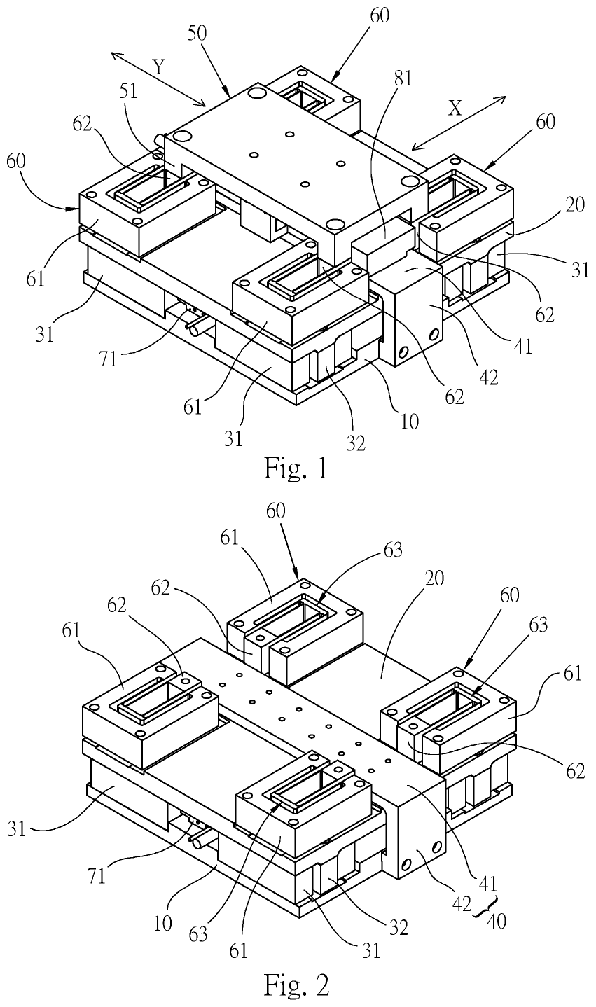

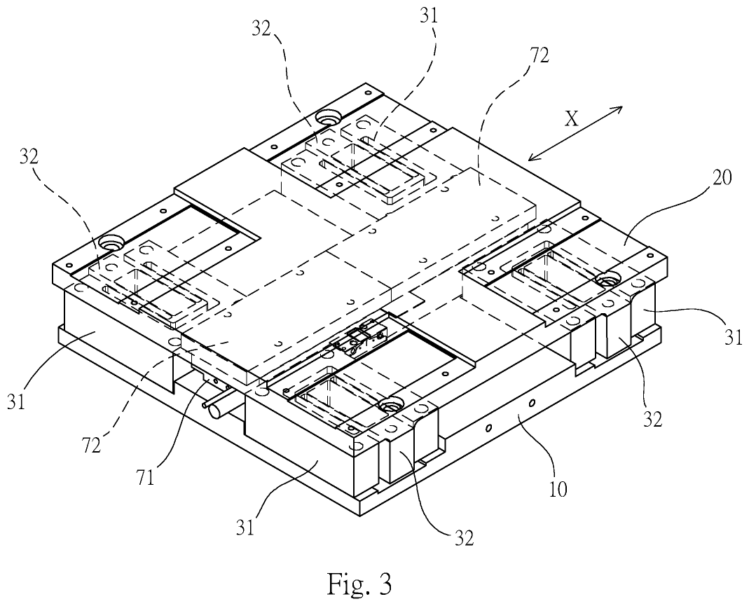

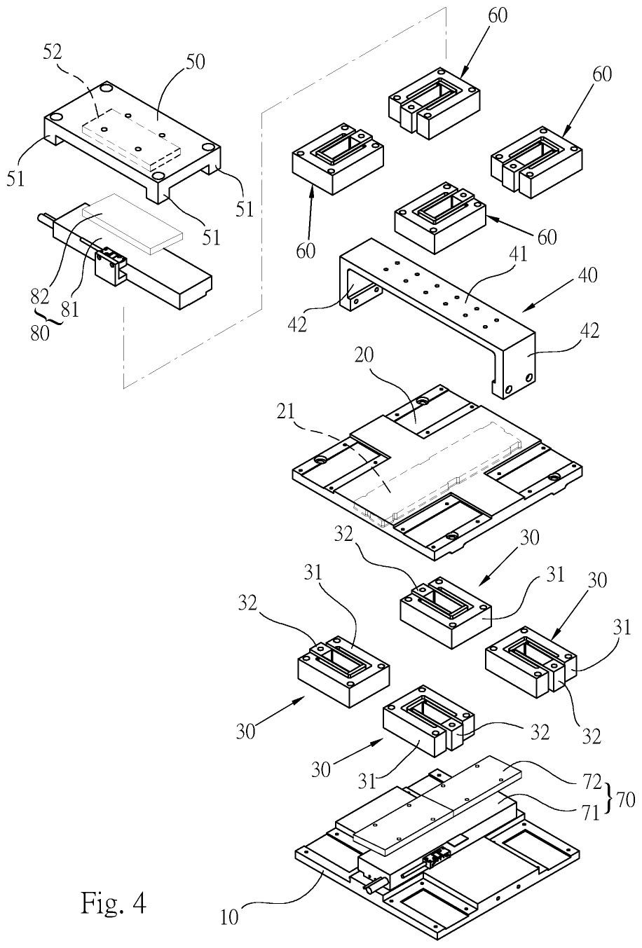

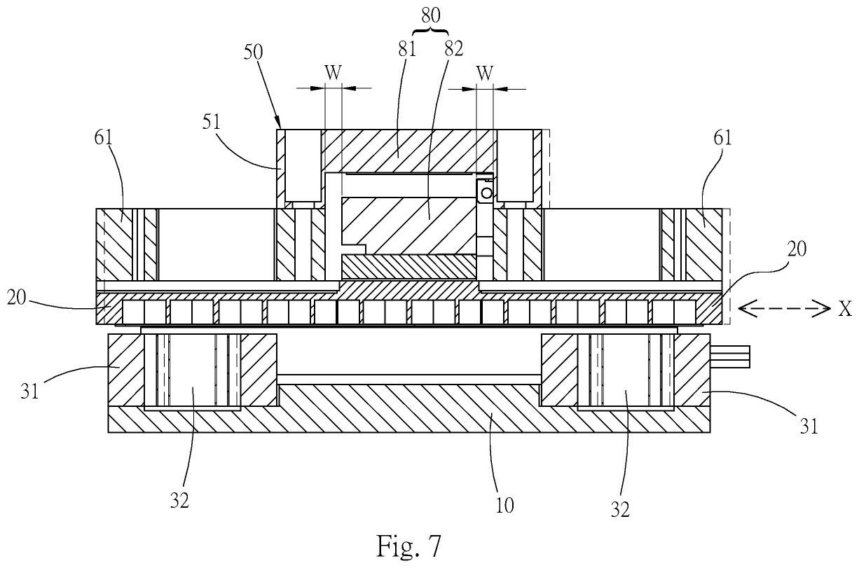

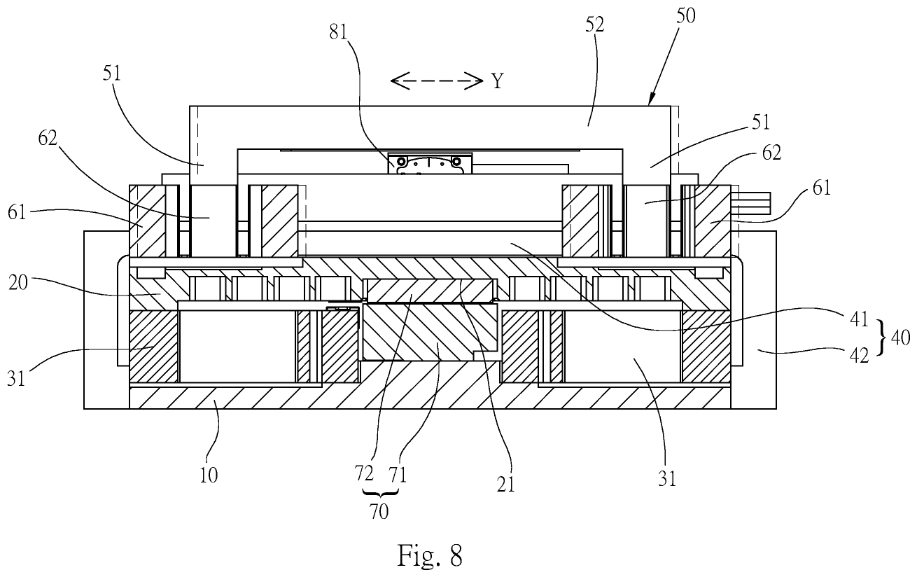

Refer to FIG. 1 to FIG. 8. The flexure stage of the first embodiment of the present invention comprises a base 10, a first carrier 20, a plurality of first flexure units 30, a gantry unit 40, a second carrier 50, and a plurality of second flexure units 60. The first carrier 20 is separated from the base 10 and reciprocated along the X-axis. The first flexure units 30 are disposed between the base 10 and the first carrier 20 to provide flexibility in the X-axis to restrict the movement of the first carrier 20. The gantry unit 40 is located on the base 10 and separated from the first carrier 20. The second carrier 50 is set on the gantry unit 40 and reciprocated along the Y-axis. The second flexure units 60 are disposed between the first carrier 20 and the second carrier 50 to provide flexibility in the Y-axis to restrict the movement of the second carrier 50. In this embodiment, the first carrier 20 and the second carrier 50 are in the form of rectangle wherein four modularized first flexure units 30 and four modularized second flexure units 60 are disposed corresponding to the corners of the first carrier 20 and the second carrier 50 respectively. Each first flexure unit 30 or each second flexure unit 60 can be exchanged individually to raise the repair convenience and decrease the maintenance cost.

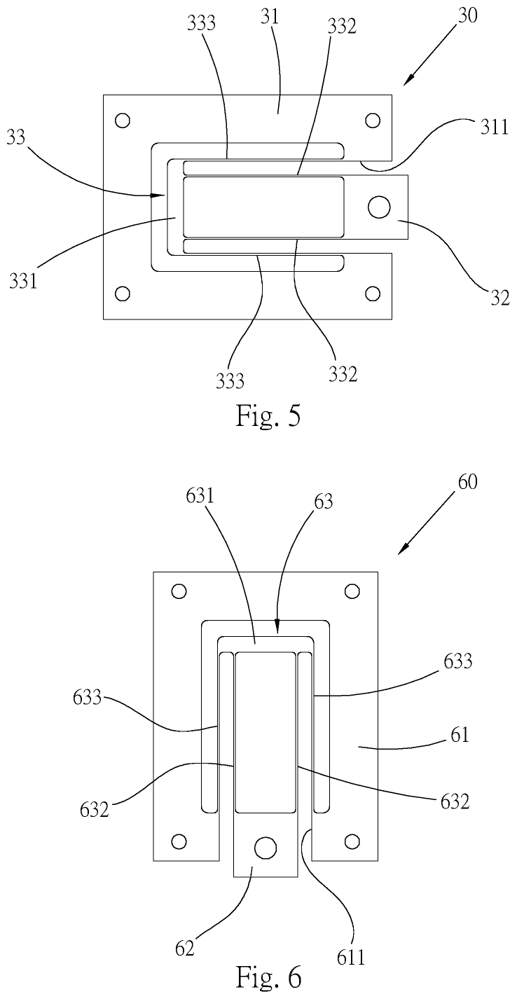

Refer to FIG. 5. Each first flexure unit 30 comprises a first section 31, a second section 32, and a first bending part 33. The first section 31 is located on the base 10. The second section 32 is connected with the first carrier 20 and separated from the first section 31. The first bending part 33 is coupled with the first section 31 and the second section 32. The first section 31 comprises an opening 311 holding the first bending part 33 and the second section 32. The first bending part 33 comprises a first connection element 331, two first elastic element 332 and two second elastic element 333 wherein the first elastic elements 332 are bridged between the first connection element 331 and the edge of the second section 32, and the second elastic elements 333 are bridged between the first connection element 331 and the wall of the opening 311 of the first section 31. The first elastic elements 332 and the second elastic elements 333 are not limited in the disclosed configuration, and can be designed in diverse arrangement, number and shape according to the requirement.

Refer to FIG. 6. Each second flexure unit 60 comprises a third section 61, a fourth section 62, and a second bending part 63 wherein the second bending part 63 comprises a third connection element 631, a third elastic element 632 and a fourth elastic element 633. The composition of the second flexure unit 60 and the second bending part 63 are equal to that of the first flexure unit 30 and the first bending part 33. The third section 61 is located on the first carrier 20, and the fourth section 62 is connected with the second carrier 50.

To shorten the setting time and position the carrier precisely after high speed movement, the flexure stage further comprises a first driving unit 70 and a second driving unit 80. The first driving unit 70 is disposed between the base 10 and the first carrier 20 to activate the first carrier 20. The second driving unit 80 is disposed between the gantry unit 40 and the second carrier 50 to activate the second carrier 50. Therefore, the flexure stage with the first flexure units 30 and the second flexure units 60 is provided to produce a compensating displacement to offset error and shorten the setting time.

The first driving unit 70 comprises a first stator 71 fixed on the base 10 and a first mover 72 positioned on the surface of the first carrier 20 facing to the base 10. The first mover 72 is propelled by a magnetic field of the first stator 71 to have the first carrier 20 reciprocated along the X-axis. The second driving unit 80 comprises a second stator 81 and a second mover 82 functioned as the first stator 71 and the first mover 72 to have the second carrier 50 reciprocated along the Y-axis. Specifically, the first mover 72 is positioned within the first indentation 21 of the first carrier 20, and the second mover 82 is positioned within the second indentation 52 of the second carrier 50.

In addition, the gantry unit 40 supports the second stator 81 of the second driving unit 80 to prevent the first driving unit 70 from being damaged because of the weight of the second mover 82. The gantry unit 40 comprises a bridge 41 above the base 10 and two connections 42 fastened at two ends of the base 10 to hold the first carrier 20 between the bridge 41 and the base 10. Therefore, the second stator 81 is not disposed in an enclosed configuration such that the heat generated from the second stator 81 can be dissipated rapidly.

The first carrier 20 and the second carrier 50 can be manufactured in a hollow structure to decrease the loading of first driving unit 70 and reduce the material cost.

The second carrier 50 comprises a plurality of fixtures 51 associated with the fourth sections 62 of the second flexure unit 60 respectively to form a space where the second driving unit 80 is disposed. Each fixture 51 is separated from the second driving unit 80 with a width W to prevent from the interference during the first carrier 20 is activated by the first driving unit 70.

It is to be understood that the above descriptions are merely the preferable embodiment of the present invention and are not intended to limit the scope of the present invention. Equivalent changes and modifications made in the spirit of the present invention are regarded as falling within the scope of the present invention.

1. A flexure stage, comprising:
a base;
a first carrier, separated from the base and reciprocated along a first axis;
a plurality of first flexure units, disposed between the base and the first carrier, wherein each of the first flexure units comprises flexibility in the first axis;
a gantry unit, located on the base and separated from the first carrier;
a second carrier, set on the gantry unit and reciprocated along a second axis; and
a plurality of second flexure units, disposed between the first carrier and the second carrier, wherein each of the second flexure units comprises flexibility in the second axis.

2. The flexure stage as claimed in claim 1, wherein the gantry unit comprises a bridge and two connections to hold the first carrier between the bridge and the base.

3. The flexure stage as claimed in claim 2, wherein each of the first flexure units comprises a first section located on the base, a second section connected with the first carrier and separated from the first section, and a first bending part coupled with the first section and the second section.

4. The flexure stage as claimed in claim 3, wherein each of the second flexure units comprises a third section located on the first carrier, a fourth section connected with the second carrier and separated from the third section, and a second bending part coupled with the third section and the fourth section.

5. The flexure stage as claimed in claim 4, wherein the first section comprises an opening holding the first bending part and the second section; the first bending part comprises a first connection element, a first elastic element and a second elastic element wherein the first elastic element is bridged between the first connection element and the edge of the second section, and the second elastic element is bridged between the first connection element and the wall of the opening of the first section.

6. The flexure stage as claimed in claim 5, wherein the third section comprises an opening holding the second bending part and the fourth section; the second bending part comprises a third connection element, a third elastic element and a fourth elastic element wherein the third elastic element is bridged between the third connection element and the edge of the fourth section, and the fourth elastic element is bridged between the third connection element and the wall of the opening of the third section.

7. The flexure stage as claimed in claim 6, wherein the second carrier comprises a plurality of fixtures associated with the fourth sections of the second flexure units respectively.

8. The flexure stage as claimed in claim 7, further comprising a first driving unit disposed between the base and the first carrier.

9. The flexure stage as claimed in claim 1, further comprising a second driving unit disposed between the gantry unit and the second carrier.

10. The flexure stage as claimed in claim 9, wherein each of the fixtures is separated from the second driving unit with a width.
